(19) United States
(12) Patent Application Publication
(10) Pub. No.: US 2026/0293591 A1
(43) Pub. Date: Sep. 24, 2026

(54) CARRIER FOR EDGE PASSIVATION

(71) Applicant: SINGULUS TECHNOLOGIES AG, Kahl am Main (DE)

(72) Inventor: Frank MAY, Frankfurt (DE)

(73) Assignee: SINGULUS TECHNOLOGIES AG, Kahl am Main (DE)

(21) Appl. No.: 19/484,137

(22) PCT Filed: Apr. 16, 2024
(86) PCT No.: PCT/EP2024/060229

§ 371 Date: Nov. 13, 2025

(30) Foreign Application Priority Data
May 16, 2023 (DE) 10 2023 112 827.2

(51) Int. Cl. H10P 72/10

(52) U.S. Cl. CPC H10P 72/15

(57) ABSTRACT

The present invention relates in general to a carrier for edge passivation of semiconductor devices and, more specifically, to a storage insert for receiving a stack of a plurality of wafers or semiconductor devices, a carrier for a plurality of such storage inserts, and a method for loading such a carrier.

The present invention relates in general to a carrier for edge passivation of semiconductor devices and, specifically, to a storage insert for receiving a stack of a plurality of wafers or semiconductor devices, a carrier for a plurality of such storage inserts, and to a method for loading such a carrier.

It is known, for example from DE 10 2018 123 485B4 , that it can be advantageous to passivate the cut edges of semiconductor devices or wafers. In order to provide these cut surfaces or cut edges with a separation surface passivation layer, it is necessary in conventional systems for applying passivation layers to align the semiconductor devices or wafers vertically, which deviates from the usual horizontal alignment of such wafers in manufacturing and coating processes. Thus, corresponding alternative carrier systems or carriers are required for passivation.

Therefore, the objective of the present invention is to provide such an alternative carrier system or a corresponding loading method that is optimized in terms of processing speed and quality.

This objective is solved by a storage insert according to claim 1, a carrier according to claims 10 and 16, and a loading method according to claims 23 and 29. Preferred embodiments of these aspects of the invention can be found, among others, in the dependent claims.

The invention is inter alia based on the idea of inserting one or more stacks of a plurality of wafers as (a) wafer package(s) rotated by 90° into one or more corresponding compartments of a carrier. The fact that the wafers are not transported individually into the carrier, as is usually the case, but in packages, means that the loading process can be significantly accelerated.

According to a first aspect of the invention, the wafer packages are not inserted directly into the carrier compartments, but first into a corresponding storage insert or tray. Accordingly, the present invention, according to a first aspect, relates to a storage insert or tray for receiving a stack of a plurality of wafers, comprising two opposing side walls and a bottom plate slidably mounted relative to the side walls for storing a stack of a plurality of wafers. Moreover, the storage insert further comprises a restoring mechanism which is adapted to exert an upward-directed restoring force (i.e., along the stacking direction) on the bottom plate parallel to the side walls.

The storage insert is preferably dimensioned so that a stack of at least 30, preferably at least 100, more preferably at least 250, even more preferably at least 500, and particularly preferably at least 1,000 wafers can be received. For this purpose, the storage insert preferably has a height of at least 1 cm, more preferably at least 2 cm, and particularly preferably at least 3 cm. The restoring mechanism preferably comprises one or more spring elements (preferably two spring elements) and/or an elastic material. The restoring mechanism is preferably adapted to exert a force between 0.1 N and 20 N, preferably between 0.5 N and 5 N, on the bottom plate. The maximum restoring force of the restoring mechanism is preferably greater than 0.1 N, more preferably greater than 0.3 N, even more preferably greater than 1 N and particularly preferably greater than 3 N.

As will be explained in detail below, the restoring mechanism serves to compress the wafer package, which is subsequently rotated by 90°, in the corresponding compartment of the carrier. This effectively prevents a gap from forming between adjacent, vertically aligned wafers, which during the passivation process could lead to parts of the top or bottom of the wafers being unintentionally coated with an electrically insulating layer.

The bottom plate can be slidably mounted on the side walls by means of the restoring mechanism. However, it is particularly preferred that the storage insert further comprises a base plate fixedly connected to the side walls and that the bottom plate is connected to the base plate via the restoring mechanism. The latter connection may be detachable or fixed. For example, one or more spring elements may be mounted on the base plate, onto which the bottom plate is loosely placed or with which the bottom plate is detachably locked. Alternatively, the bottom plate may also be fixedly connected to spring elements attached to the base plate.

The side walls of the storage insert preferably each comprise on their inner side along an edge a projection or web as a rest for the wafer stack. Hence, if the storage insert with the wafer stack is rotated by 90°, the wafers, which are now vertically aligned, rest with their edges on these projections or webs. This effectively prevents the wafers from falling out of the storage insert when the storage insert is rotated. Furthermore, all edges are aligned flush, which prevents mutual shadowing due to projections.

On their outer side, the side walls of the storage insert preferably each comprise a receptacle for a handling device. This may be, for example, one or more of the following components: hook, eyelet, a raised or recessed structure which allows a form-fitting grip, ensuring precise positioning and rotation.

The storage insert preferably comprises a stack of a plurality of wafers which rests on the bottom plate. The storage insert preferably comprises at least 100, more preferably at least 250, even more preferably at least 500, and particularly preferably at least 1,000 wafers. Preferably, the wafers have essentially the same base area as the bottom plate. This means that the ratio of the bottom plate length to the wafer length and/or of the bottom plate width to the wafer width is less than 1.05, more preferably less than 1.03, and particularly preferably less than 1.01. The wafer stack preferably abuts the projections or webs on the inner sides of the side walls, wherein one edge of each wafer preferably contacts the projections or webs. The invention also relates to the storage insert that is rotated by 90°, in which the bottom plate is aligned vertically and the wafers of the stack rest on the projections or webs of the side walls.

According to a second aspect, the present invention is directed to a carrier for one or more storage inserts as described above, wherein the carrier comprises a frame and one or more compartments for one or more storage inserts as described above.

Each compartment of the carrier is preferably delimited by at least one web, preferably by two webs opposite each other, so that in case of a plurality of compartments, the two adjacent compartments are separated from one another other by a web arranged between them. If there is only one compartment, the two webs delimiting this compartment preferably form part of the frame at the same time. In other words, in this case, the compartment can also be formed or defined by the frame parts, so that in this case the following features relating to the webs can analogously relate to frame parts.

Preferably, each web comprises at least one, more preferably two, recess(es).

Preferably, in at least one of the compartments a storage insert as described above is received, which was rotated by 90° so that the bottom plate is aligned vertically. Preferably, a storage insert as described above is received in a plurality of, particularly preferably in all of, the compartments.

The carrier preferably comprises at least 10, more preferably at least 25, even more preferably at least 50, and particularly preferably at least 100 compartments.

Preferably, the storage insert received in the respective compartment comprises a wafer stack which is preferably clamped between the bottom plate of the storage insert and the web (or frame part) delimiting the compartment. For this purpose, the storage insert is preferably introduced into the compartment in such a way that the bottom plate of the storage insert is arranged parallel to and adjacent to a web (or frame part) delimiting the compartment and the topmost wafer of the wafer stack is adjacent to the second web (or frame part) delimiting the compartment. Since the restoring mechanism of the storage insert exerts an upward-directed restoring force on the bottom plate parallel to the side walls (in the regular orientation), the restoring mechanism presses the wafer stack, which is now rotated by 90°, against the web (or frame part) delimiting the compartment. The restoring mechanism is to preferably press the wafer stack against the web (or frame part) delimiting the compartment with a force between 0.1 N and 20 N, more preferably with a force between 0.5 N and 5 N.

If the web (or frame part) adjacent to the topmost wafer in the wafer stack comprises one or more recesses, these should preferably be arranged so that they do not overlap with electrical contacts in said topmost wafer, so that no material passes onto the electrical contacts during the passivation step. If this is not possible, passivation can alternatively be carried out with a dummy wafer as the topmost wafer, which is preferably used several times and shields the wafer below it in the stack from material.

In principle, the carrier and the storage insert can be made of any materials, which should, however, be able to withstand edge passivation without damage, so that their melting point should preferably be greater than 200° C., more preferably greater than 300° C., and particularly preferably greater than 400° C. Examples of materials for the storage insert and/or the carrier are: steel, aluminum, titanium, polyetheretherketone (PEEK), polytetrafluoroethylene (PTFE), polyamide-imide (PAI), polyphenylsulfone (PPS).

According to a third aspect, the invention relates to a method for loading a carrier as described above. In the context of this method, a storage insert as described above is first provided and a stack of a plurality of wafers is introduced into the storage insert such that the wafer stack rests on the bottom plate of the storage insert. The storage insert is then rotated by 90° so that the bottom plate is aligned vertically and, preferably, the wafers of the stack rest on the projections or webs of the side walls of the storage insert. The wafer stack is further compressed, and the compressed and rotated wafer stack is then introduced into a compartment of the carrier. The rotation of the storage insert can be carried out before, after or simultaneously with the compression. When compressing the wafer stack, in particular the restoring mechanism is biased against its restoring force so that, after the wafer stack was introduced into the compartment of the carrier, the restoring mechanism presses the wafer stack against the web (or frame part) delimiting the compartment, as already described above. Accordingly, the force during compression is preferably greater than the restoring force of the restoring mechanism.

Preferably, the storage insert is rotated, the wafer stack is compressed, and the stack is introduced into the compartment by means of a handling device or robot arm. For this purpose, the side walls of the storage insert preferably each comprise a receptacle on their outer side for a corresponding counterpart of the handling device or robot arm, which engages with these receptacles during or before rotation and compression. The handling device or robot arm also preferably comprises a pressing mechanism to compress the wafer stack or press it against the return mechanism.

As already explained above, the webs delimiting the compartments may comprise one or more recesses. These may be provided so that the pressing mechanism can enter at least partially into these recesses when the compressed and rotated wafer stack is introduced into the compartment of the carrier. The pressing mechanism can then detach from the wafer stack and be withdrawn through the recesses so that the restoring mechanism can press the wafer stack against the web.

According to a fourth aspect, the present invention also relates to an alternative carrier for one or more horizontally aligned wafer stacks, wherein the carrier comprises a frame and one or more compartments, each for one or more horizontally aligned wafer stacks. Each compartment of the carrier is preferably delimited by at least one web, preferably by two webs opposite to each other, so that, if there are a plurality of compartments, the two adjacent compartments are separated from each other by a web arranged between them, and wherein a horizontally aligned stack of wafers is received in at least one of the compartments in such a way that the wafers in the compartment are vertically aligned and arranged parallel to the web or webs.

If there is only one compartment, the two webs delimiting said compartment preferably form part of the frame at the same time. In other words, in this case, the compartment can also be formed or defined by the frame parts, so that in this case the following features relating to the webs can analogously relate to frame parts.

Accordingly, in this fourth aspect of the invention, the storage insert discussed above is dispensed with and the wafer stack is inserted directly into a corresponding compartment of the carrier.

Thus, the wafer stack is preferably clamped directly or indirectly between two webs (or frame parts) delimiting the compartment. Each web may also comprise one or more (preferably two) recesses.

In this fourth aspect of the invention, each compartment preferably comprises a compression mechanism that compresses the wafer stack in the compartment in the stacking direction, preferably with a force between 0.1 N and 20 N, more preferably with a force between 0.5 N and 5 N. The compression mechanism may comprise one or more, preferably two, spring elements and/or an elastic material, which is/are arranged inside the compartment. Preferably, the compression mechanism is attached detachably or fixedly to one of the webs (or frame parts) delimiting the compartment. For example, a spring plate can be attached to a web (or frame part) by means of one or more springs. Alternatively, the compression mechanism may also be attached, detachably or fixedly, to one or both of the side walls delimiting the compartment.

Finally, according to a fifth aspect, the present invention relates to a method for loading the carrier according to the fourth aspect. In this method, a stack of a plurality of wafers is initially provided and then the wafer stack is introduced into a compartment of a carrier such that the wafers are vertically aligned in the compartment and arranged parallel to the webs (or frame parts) of the carrier, wherein introducing is preferably carried out while overcoming the restoring force applied by the compression mechanism.

In this case, too, introducing is preferably carried out by means of a handling device or robot arm. Said handling device preferably comprises a pressing mechanism which biases the compression mechanism when the stack of wafers is introduced.

If, for example, the spring plate already mentioned above is attached to a web of the compartment by means of one or more springs, the pressing mechanism of the handling device can initially press the spring plate against the restoring force of the springs in the direction of the web, thereby enlarging the compartment accordingly. The handling device can then introduce the wafer stack into the enlarged compartment and subsequently detach itself from the spring plate, so that the latter acts on the wafer stack by means of the restoring force of the springs and presses the stack against the opposite web. In this case, too, corresponding recesses may be provided on the webs into which the pressing mechanism can enter. However, this is not absolutely necessary, since, for example, corresponding receptacles for the pressing mechanism may also be provided between the web and the spring plate, so that the pressing mechanism can be released from the compression mechanism without corresponding recesses.

Preferred embodiments of the present invention are described in more detail below with reference to the figures.

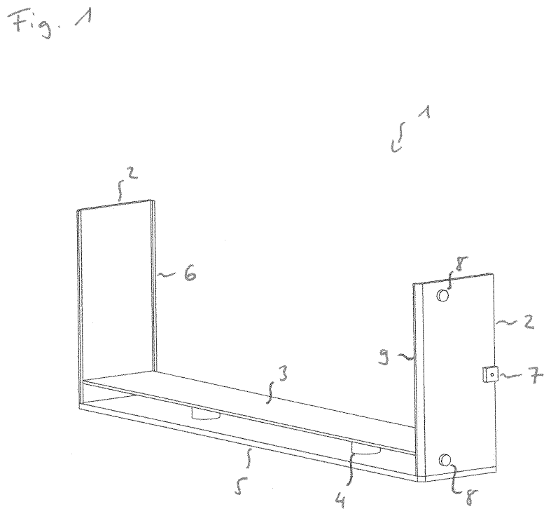

FIG. 1 shows a storage insert according to a preferred embodiment of the present invention in perspective view;

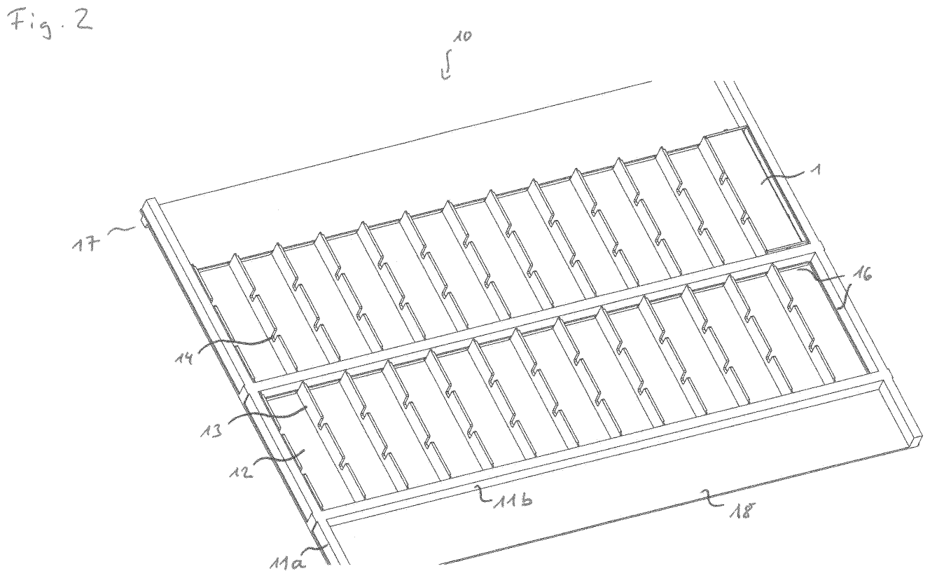

FIG. 2 shows a carrier according to a preferred embodiment of the present invention in perspective view;

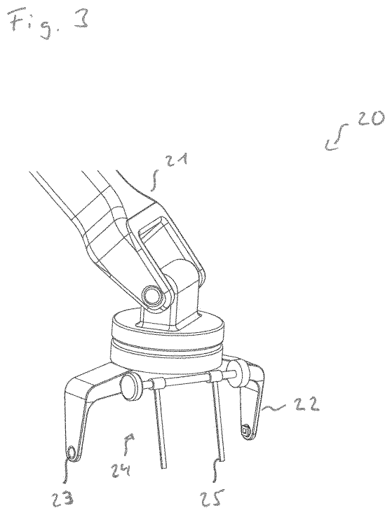

FIG. 3 shows a handling device for use in the method according to the invention in perspective view;

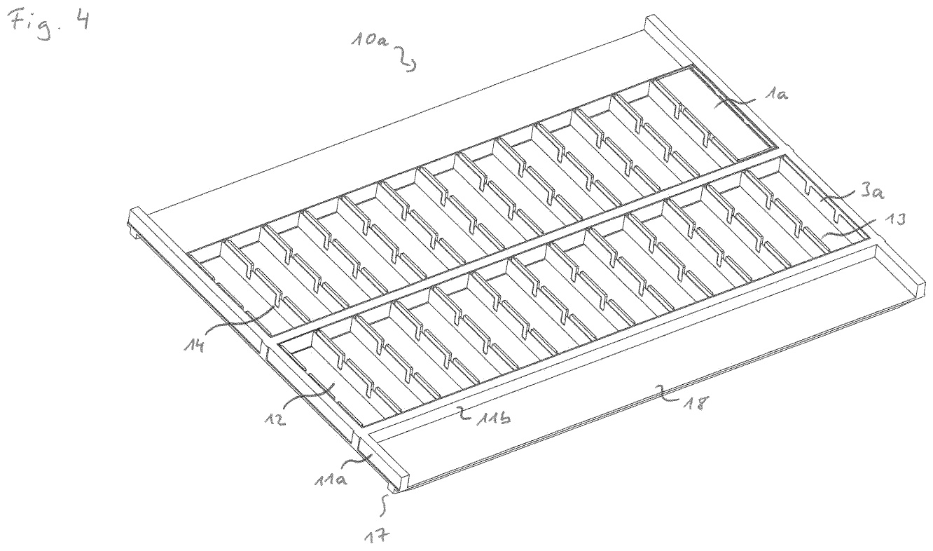

FIG. 4 shows a carrier according to a further preferred embodiment of the present invention in perspective view; and

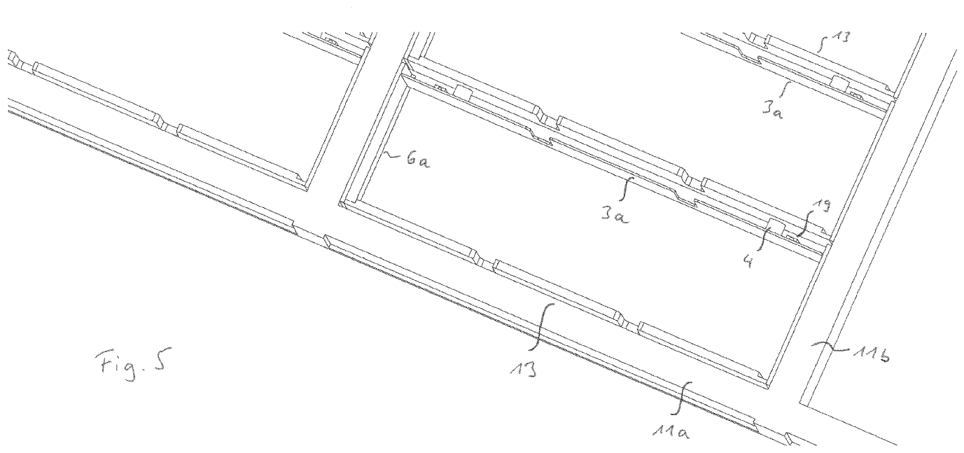

FIG. 5 shows a section of the carrier according to FIG. 4.

FIG. 1 shows a storage insert in perspective view according to a preferred embodiment of the first aspect of the invention. The storage insert or tray 1 for receiving a stack of a plurality of wafers or semiconductor devices (not shown) comprises two opposing side walls 2 and a bottom plate 3 slidably mounted relative to the side walls 2 for storing a stack of a plurality of wafers (not shown). Furthermore, a restoring mechanism 4 is provided which is adapted to exert an upward-directed restoring force on the bottom plate 3 parallel to the side walls 2. In the preferred embodiment shown, the restoring mechanism is formed by two schematically indicated spring elements 4, via which the bottom plate 3 is connected to a base plate 5, which is connected to the side walls 2. The bottom plate 3 can be fixedly connected to the two spring elements 4 or rest loosely on them. As an alternative, instead of the two springs 4, a single, larger leaf spring or a layer of elastic material could also be used to exert an upward-directed restoring force on the bottom plate 3.

As can be readily seen, the base plate 5 is not necessary for the invention since the restoring mechanism could also be attached directly or indirectly to the two side walls 2, for example. The two side walls 2 each comprise on their inner side along an edge a projection or a web 6, serving as a rest for the wafer stack once the storage insert 1 was rotated by 90°. In the preferred embodiment shown in FIG. 1, each of the side walls 2 comprises such a projection or web 6 on both inner edges, which is, however, not necessary.

On their outer side, the side walls 2 each comprise a receptacle 7 for a handling device 20 (see FIG. 3). Preferably, the receptacle 7 can engage in a form-fitting manner with a corresponding counterpart in the handling device 20.

Furthermore, two lower rest points 8 are provided on the outer side of each side wall 2, which serve to rest on corresponding rests in the carrier, as explained in more detail below.

Moreover, the outer sides of the side walls 2 each comprise an insertion chamfer 9 on one side edge, which is intended to facilitate insertion of the storage insert 1 into the carrier 10.

FIG. 2 shows a perspective view of a carrier 10 according to a preferred embodiment of the second aspect of the invention for a plurality of storage inserts 1, for example for a plurality (here: 26) of storage inserts as shown in FIG. 1. The carrier 10 comprises a frame 11a, 11b and a plurality of compartments 12, each for a storage insert 1. The frame may also have the shape of a base plate 18 in sections and may, for example, be provided with running strips 17 for easy processing. The individual compartments 12 preferably have no bottom in order to allow passivation of the wafer stack from below if necessary. Instead, support webs 16 are preferably provided, which carry the support points 8 of the storage insert 1 (see FIG. 1).

In the preferred embodiment shown, the compartments 12 are separated from one another by webs 13, so that each compartment 12 is formed by two webs 13 and by two sections of the lateral frame elements 11b. In the case of the edge compartments, the compartment could also be delimited on one side by a section of the frame 11a. In the preferred embodiment shown, the webs 13 each have two recesses 14 for the pressing mechanism 25 of the handling device 20 (see FIG. 3).

As a matter of course, the frame 10 may also comprise more or fewer than the 26 compartments shown in the example. In particular, the frame 10 could also comprise only a single compartment 12, which would then preferably be delimited by frame parts 11a, so that the webs 13 would not be necessary.

An example of a handling device 20 is shown in perspective in FIG. 3. The handling device 20 comprises, among other things, a gripping arm 21 with a receiving mechanism 22 and a pressing mechanism 24. The receptacle mechanism 22 comprises the counterparts 23 already mentioned above for the receptacles 7 in the side walls 2 of the storage insert 1, with which they can engage in a form-fitting manner. This allows to lift a loaded storage insert 1 and rotate it by 90°. In the preferred embodiment shown, the pressing mechanism 24 comprises two arms 25 which can press the wafer stack towards the base plate 5 and thereby overcome the restoring force of the restoring mechanism 4.

The storage insert 1 with the wafer stack compressed in this manner can then be introduced into a compartment 12 of the carrier 10, the two arms 25 of the pressing mechanism 24 entering into the recesses 14 provided for this purpose in the associated web 13 when the pressing mechanism is released. The handling device 20 is then withdrawn and the restoring forces of the restoring mechanism 4 press the bottom plate 3 together with the wafer stack in the direction of the opposite web 13.

FIG. 4 shows a perspective view of a preferred embodiment of a carrier 10a according to the fourth aspect of the invention, which renders the use of the storage insert 1 obsolete. The carrier 10a according to FIG. 4 also comprises a frame 11a, 11b and a plurality of compartments 12, each for a horizontally aligned wafer stack, wherein the compartments 12 are separated from one another by webs 13 and wherein a horizontally aligned wafer stack 1a is received in at least one of the compartments 12 in such a way that the wafers (not shown individually in FIG. 4) are vertically aligned in the compartment 12 and arranged parallel to the webs 13.

In this variant, it is also preferred that each compartment has a compression mechanism 3a, 4 which compresses the wafer stack 1a in the compartment 12 in the stacking direction in order to prevent free spaces between adjacent wafer edges as effectively as possible. In the preferred embodiment shown (see in particular the detailed view in FIG. 5), the compression mechanism comprises a spring plate 3a which is resiliently mounted on the adjacent web 13 by means of two spring elements 4, so that the inserted wafer stack 1a is compressed between a web 13 on the one hand and the spring plate 3a on the other hand.

In FIGS. 4 and 5, the webs 13 are also provided with corresponding recesses 14, which allow the two arms 25 of the pressing mechanism 24 to enter into them. However, this is not necessary in the preferred embodiment shown, since here the pressing mechanism can enter into the space between the web 13 and the spring plate 3a. For this purpose, the preferred embodiment shown provides two receptacles 19 for the handling device, which enable the handling device to engage with the spring plate 3a and pull it against the restoring force of the springs 4 in the direction of the adjacent web 13. The wafer stack can then be inserted into the compartment 12 enlarged in this way. After the handling device is withdrawn, the spring plate 3a is pressed against the wafer stack by means of the springs 4 and the wafer stack is pressed onto the opposite side in the direction of the web 13.

1. A storage insert for receiving a stack of a plurality of wafers, the storage insert comprising:
two opposing side walls;
a bottom plate slidably mounted relative to the side walls for storing the stack of the plurality of wafers; and
a restoring mechanism which is adapted to exert an upward-directed restoring force on the bottom plate parallel to the side walls.

2. The storage insert according to claim 1, wherein the storage insert further comprises a base plate connected to the side walls, and wherein the bottom plate is connected, detachably or fixedly, to the base plate via the restoring mechanism.

3. (canceled)

4. The storage insert according to claim 1, wherein the restoring mechanism is adapted to exert a force between 0.1 N and 20 N, on the bottom plate.

5. The storage insert according to claim 1, wherein the side walls each comprise on their inner side along an edge a projection or a web as a rest for the wafter stack.

6-15. (canceled)

16. A carrier for one or more horizontally aligned wafer stacks, wherein the carrier has a frame and one or more compartments for a respective horizontally aligned wafer stack, wherein each compartment is delimited by at least one web and/or wherein the plurality of compartments are each separated from one another by webs, and wherein a horizontally aligned wafer stack is received in at least one of the compartments such that the wafers in the compartment are vertically aligned and arranged parallel to the web or the webs.

17. The carrier according to claim 16, wherein each web comprises at least one recess.

18. The carrier according to claim 16, wherein the wafer stack is clamped between two webs delimiting the compartment.

19. The carrier according to claim 16, wherein each compartment comprises a compression mechanism which compresses the wafer stack in the compartment in the stacking direction with a force between 0.1 N and 20 N.

20. (canceled)

21. The carrier according to claim 19, wherein the compression mechanism is attached to one of the webs delimiting the compartment.

22. The carrier according to claim 19, wherein the compartment comprises side walls oriented perpendicular to the webs, and wherein the compression mechanism is attached to one or both of the side walls.

23. A method for loading a carrier, the method comprising:
a) providing a storage insert according to claim 1;
b) introducing the stack of the plurality of wafers into the storage insert such that the stack of wafers rests on the bottom plate of the storage insert;
c) rotating the storage insert by 90° so that the bottom plate is aligned vertically;
d) compressing the wafer stack; and
e) introducing the compressed and rotated wafer stack into a compartment of the carrier.

24. The method according to claim 23, wherein the force during compression is greater than the restoring force of the restoring mechanism.

25. The method according to claim 23, wherein steps c) to e) are carried out by means of a handling device.

26. The method according to claim 25, wherein the side walls of the storage insert each comprise on their outer side a receptacle for the handling device, and wherein the handling device engages with the receptacles in step c).

27. The method according to claim 25, wherein the handling device comprises a pressing mechanism, and wherein step d) is carried out by means of the pressing mechanism.

28. The method according to claim 27, wherein the compartments of the carrier are separated from one another by webs, wherein each web comprises at least one recess, and wherein the pressing mechanism in step e) enters at least partially into the at least one recess.

29. A method for loading the carrier according to claim 16, the method comprising
a) providing a stack of a plurality of wafers;
b) introducing the wafer stack into a compartment the carrier such that the wafers are vertically aligned in the compartment and arranged parallel to the web or webs of the carrier, wherein the introducing is carried out while overcoming a restoring force applied by a compression mechanism on the wafer stack.

30. The method according to claim 29, wherein step b) is carried out by means of a handling device.

31. The method according to claim 29, wherein the handling device comprises a pressing mechanism, and wherein in step b) the pressing mechanism biases the compression mechanism, the wafer stack is introduced into the compartment and subsequently the compression mechanism compresses the wafer stack in the compartment.

32. The method according to claim 31, wherein the webs of the compartments comprise each at least one recess, and wherein the pressing mechanism in step b) enters at least partially into the at least one recess.
